(19) United States
(12) Patent Application Publication
(10) Pub. No.: US 2012/0053867 A1
(43) Pub. Date: Mar. 1, 2012

(54) SYSTEM AND METHODS FOR HIGH-PRECISION STRING-LEVEL MEASUREMENT OF PHOTOVOLTAIC ARRAY PERFORMANCE

(75) Inventors: Lawrence Dunn, Austin, TX (US); Michael Gostein, Austin, TX (US); William Stueve, Austin, TX (US)

(73) Assignee: ATONOMETRICS, INC., Austin, TX (US)

(21) Appl. No.: 13/216,306

(22) Filed: Aug. 24, 2011

Related U.S. Application Data
(60) Provisional application No. 61/376,634, filed on Aug. 24, 2010.

(51) Int. Cl. G01R 31/26; G06F 19/00

(52) U.S. Cl. 702/58

(57) ABSTRACT

A system and methods for measuring the performance of individual strings of photovoltaic (PV) modules in a PV array, including a string combiner box with integrated capability for measurement of string current versus voltage (I-V) characteristics. The system may include calibrated solar insolation reference devices; environmental meters; and/or at least one system computer. The string combiner box allows: high precision string performance measurement during normal power generating operation; isolation of individual strings or groups of strings; and the performance of high-precision full I-V sweeps on individual strings. Methods are provided to analyze measured I-V curves to compensate for the effects of temperature and other variables thereby increasing PV module performance measurement accuracy. Methods are further provided to incorporate data from insolation reference devices and/or environmental meters to extract meaningful parameters from collected data regarding PV module efficiency and degradation, and track string-level performance and degradation over extended periods of time.

### RELATED APPLICATION

This application claims the priority of U.S. Provisional No. 61/376,634 entitled “SYSTEMS AND METHODS FOR HIGH-PRECISION STRING-LEVEL MEASUREMENT OF PHOTOVOLTAIC ARRAY PERFORMANCE” and filed on Aug. 24, 2010.

### FIELD OF THE INVENTION

The invention relates to high-precision measurement of performance and degradation of individual photovoltaic (PV) modules or groups of PV modules in a solar energy system. A system and methods are provided that enable measuring the electrical output of PV modules in a PV array during normal operation. The system enables measurement of current versus voltage characteristics of individual PV modules or groups of PV modules; methods are provided to extract meaningful performance data from these characteristics.

### BACKGROUND OF THE INVENTION

Photovoltaic (PV) solar energy generation systems are becoming increasingly desirable as the cost of conventional energy generation increases and interest in renewable energy sources grows.

Performance monitoring of PV systems is becoming increasingly important. A PV system has considerable cost, which is expected to be amortized over the lifetime of the system. However, system performance typically degrades over time and is affected by exposure to outdoor conditions. Failure or degradation of individual elements or groups of elements within a PV system reduces the system output power and may also decrease system lifetime, thereby increasing the average cost per unit of energy generated.

System operators and owners therefore monitor the output power of their systems carefully in order to compare performance with design expectations and to identify faults or degradations that can be remedied with maintenance. In many systems monitoring is performed continuously by automated units that transmit data to remote computers for data logging and analysis.

A PV system is typically implemented as an array of individual panels, referred to as PV modules. Each module contains multiple solar cells, which are electrically connected in series and parallel combinations in order to produce the desired output voltage and current characteristics for the module. A variety of technologies are in use for solar cell and module fabrication. The output characteristics of a PV module depend on the type and number of cells it contains and on their electrical arrangement.

FIG. 1 illustrates the typical layout of a PV array system. Individual modules are connected in series to form one or more strings having desired output voltage; multiple strings are combined in parallel at one or more string-combiner boxes to aggregate power; and the output of the string combiner(s) is fed to one or more inverters which convert the direct current (DC) output of the PV modules to alternating current (AC). Metering circuits and/or other power monitors measure the total output power of the system. Output power data are used to record energy units generated as well as for overall system-level monitoring.

Establishing expectations for system performance presents challenges, because the performance of an array of PV modules depends on many factors. These factors include ambient conditions, such as the solar insolation level at the installation site, the temperature of the modules, and the atmospheric conditions, all of which are continuously variable. Additional factors may include the degree of mismatch of electrical parameters between modules in strings, the amount of soiling PV modules undergo at the installation site, the rate of degradation of PV module performance, and the rate of degradation of the DC to AC inverter(s).

When system performance does not match expectations, it is desirable to identify any components—including PV modules—that may be at fault. Early detection of even small faults or degradations allows operators to take corrective actions that improve system performance. Therefore, PV systems typically include system-level monitoring of output power. Some systems also provide for monitoring the current output of each string of modules in a PV array (“string-level monitoring”). String-level monitoring provides a greater degree of measurement resolution as compared with system-level monitoring alone.

Additionally, high accuracy energy yield measurements over extended periods of time are desirable in order to allow operators of PV arrays to verify compliance with PV module manufacturers' warranties for module performance. Operators of PV arrays must therefore be able to measure the absolute power output of installed PV modules normalized by the insolation level of the site and corrected for effects of temperature variations. PV systems therefore often include insolation and temperature measurement devices. Furthermore, it is desirable to measure the annual output power degradation rate of the PV modules. Degradation rates specified in typical warranties are between 0.5% and 1.0% per year.

However, high-precision measurement of system performance is challenging.

The electrical measurement accuracy of existing string-level current monitoring systems is typically only in the range of +/−1% to +/−5%. Many problems may still go undetected at this level of accuracy. There exists the need for increased measurement and diagnostic capabilities at the string level in order to determine whether problems are present that would be difficult or impossible to detect through typical string monitoring solutions currently employed.

Furthermore, measurements of PV output power must be normalized by measured insolation in order to determine the energy yield of the system. Uncertainties in insolation measurement are typically in the range of +/−1% to +/−5%, even using the best available equipment.

Accurately and quickly establishing system and/or string degradation rates requires overcoming multiple challenges. Establishing degradation rates requires the long-term collection of module efficiency data that are consistent with module efficiency data recorded in the past. Because different strings of PV modules may experience degradation at different rates, it is desirable to collect data at the string level.

Typical string-level current monitoring solutions employ hall-effect current measurement devices with typical uncertainties of +/−1% to +/−5%. Uncertainties this large mean that establishing string-level degradation rates to the limits specified by a PV module manufacturer's warranty could take 5 years or more—a significant fraction of the typical 25 year life time specified for PV module installations. There exists the need to be able to determine whether the degradation rate of a PV string is within the degradation rate specified by the PV module manufacturer within ˜1 year of the initial installation of the system.

Additionally, typical string-level current monitoring solutions can measure current only at the string operating voltage. All strings connected in parallel to a single inverter input must operate at the same voltage. Because no two strings are exactly alike, they cannot all operate at their individual true maximum power voltages and currents. If the output from individual strings is mismatched due to, e.g., soiling, temperature variations, or manufacturing variability, system performance may suffer for reasons that are not due to inherent degradation of the PV modules themselves. Therefore this type of conventional string-level current monitoring solution is not capable of definitively assigning causes to changes in string performance or for measurement of inherent degradation of string-level performance.

Because of the difficulties inherent in accurately monitoring the performance of a PV array, as well as the difficulties inherent in measuring the degradation of system performance at the string level, and the potentially significant economic impact string degradation may have on the performance of a PV array, there exists the need for high-accuracy initial energy yield measurements to serve as a benchmark for system performance before any degradation due to system aging has taken place.

Finally, PV module strings or systems may experience decreases in power output due to multiple sources simultaneously. These sources include, but may not be limited to: temperature, soiling, spectral variation of the solar insolation, the magnitude of the solar insolation, changes in internal resistances or recombination rates of the PV module or string, and changes in the series resistances of interconnections between PV modules in a string. Furthermore, because the performance of a PV array is influenced by several factors, there exists the need to analyze performance and monitoring data of PV strings in order to determine the root cause of any changes in the PV string performance.

### BRIEF SUMMARY OF THE INVENTION

The disclosed subject matter provides systems and methods for determining the expected initial performance level of an array of PV modules, monitoring the performance of the array with a high degree of precision, performing current and voltage (I-V) sweep measurements on individual strings of modules in the array, and using the data collected to determine degradation rates of individual strings of modules. The systems and methods also allow the detection of other problems with PV module performance on a string level, including mismatched or damaged modules in a string and soiling of PV modules.

The systems include a string combiner box and/or switching system at which strings of modules are connected together in parallel before being connected to an inverter, wherein the string combiner box includes integrated string-level I-V measurement capability. The systems may further comprise PV reference cells and/or PV reference modules and/or other devices for accurately measuring solar insolation; devices for measuring ambient temperature and wind speed; devices for measuring the temperature of the PV modules; devices for measuring the spectrum of the incident solar insolation; and a site computer that receives signals, performs data analysis, diagnoses system performance, and optionally transmits the data to a remote computer for analysis and/or remote access.

Methods are provided to analyze measured I-V curves in order to compensate for the effects of temperature and other variables and thereby increase the accuracy of measurements of PV module performance.

Methods are further provided to incorporate data from insolation reference devices and/or environmental meters to extract meaningful parameters from collected data regarding PV module efficiency and degradation, and track string-level performance and degradation over extended periods of time.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of the claims.

### BRIEF DESCRIPTIONS OF THE DRAWINGS

At least some of the novel features believed characteristic of the invention are set forth in the claims. The invention itself, however, as well as a preferred mode of use, further objectives, and advantages thereof, will best be understood by reference to the following detailed description of an illustrative embodiment when read in conjunction with the accompanying drawings, wherein:

FIG. 1 depicts a typical photovoltaic array system, including elements for string-level monitoring, according to the prior art.

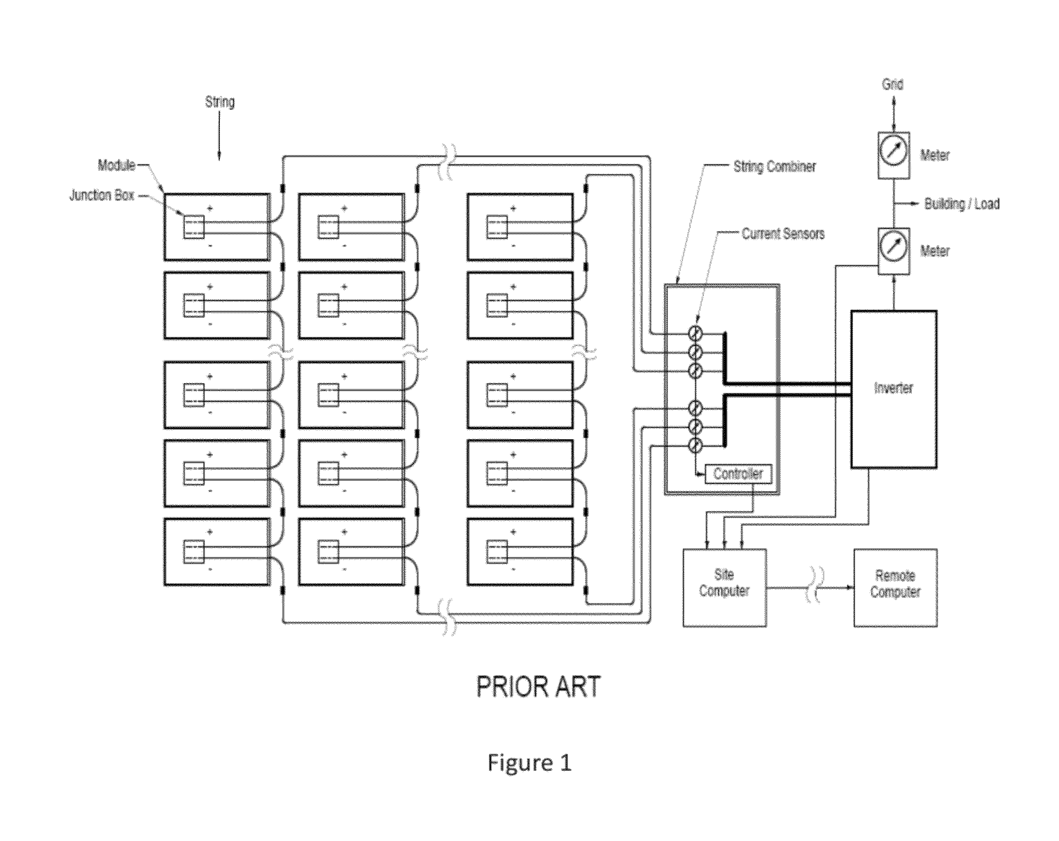

FIG. 2 depicts a string combiner box capable of both accurate string level monitoring and string level I-V sweeps as well as depicting a block diagram showing both a conventional string combiner box and the strings of PV modules connected in parallel at the conventional string combiner box.

FIG. 3 depicts a block diagram showing a string combiner box capable of accurate string level current monitoring, string level I-V sweeps, and module level I-V sweeps.

FIG. 4 depicts a block diagram illustrating the strategy for overlapping calibrations of the calibrated reference devices in order to minimize drift errors in calibrations over time.

FIG. 5 illustrates an ideal illuminated I-V curve of a PV cell, PV module, or string of PV modules.

FIG. 6 depicts the effects on an ideal illuminated I-V curve of a PV cell, PV module, or string of PV modules with varying temperature and varying light intensity.

FIG. 7 depicts multiple I-V curves of a string, illustrating several of the ways in which non-ideal behavior may be exhibited in the I-V curve.

FIG. 8 depicts a block diagram of the PV string combiner with integrated I-V measurement system.

FIG. 9 depicts an embodiment of the string disconnect switch in which two MOSFETs controlled by an opto-isolator are used to protect a disconnect relay.

FIG. 10 depicts another embodiment of the string disconnect switch in which two MOSFETs are used to protect a disconnect relay.

FIG. 11 depicts an exemplary computer system with which the disclosed subject matter could be implemented.

In the figures, like elements should be understood to represent like elements, even though reference labels are omitted on some instances of a repeated element, for simplicity.

### DETAILED DESCRIPTION OF ILLUSTRATIVE EMBODIMENTS

Although described with particular reference to systems and methods for high-precision measurement of PV array performance, those with skill in the arts will recognize that the disclosed embodiments have relevance to a wide variety of areas in addition to those specific examples described below.

All references, including publications, patent applications, and patents, cited herein are hereby incorporated by reference to the same extent as if each reference were individually and specifically indicated to be incorporated by reference and were set forth in its entirety herein.

### Overview

The disclosed subject matter provides systems and methods for accurately determining the initial performance level of an array of PV modules, monitoring the performance of the array with a high degree of precision, performing current and voltage (I-V) sweep measurements on individual strings of modules in the array, and using the data collected to determine degradation rates of individual strings of modules. The systems and methods also allow the detection of other problems with PV module performance on a string level, including mismatched or damaged modules in a string and soiling of PV modules.

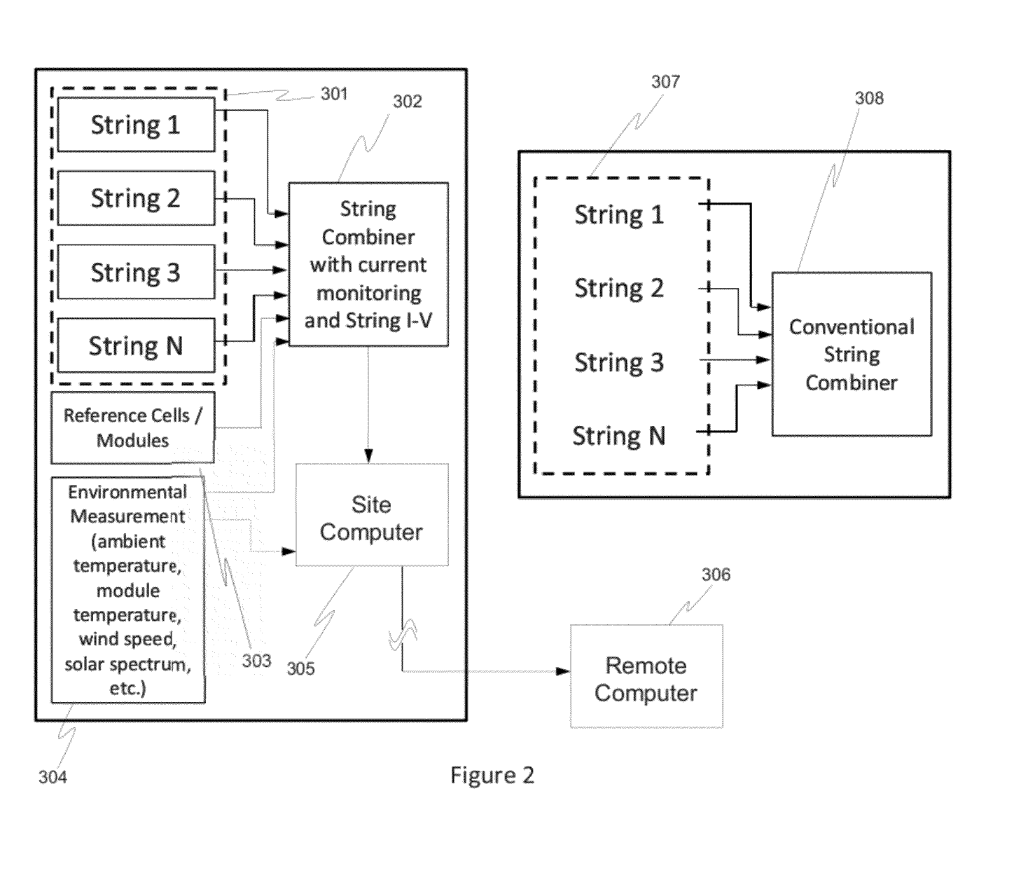

FIG. 2 depicts a block diagram showing a conventional string combiner box 308 for strings of PV modules 307 according to the prior art. FIG. 2 also depicts a string combiner box 302 according to the disclosed subject matter wherein the string combiner box 302 includes both accurate string level monitoring and string level I-V sweep capability, with N strings combined in parallel 301 before being connected to an inverter (not shown). The system may further comprise PV reference cells and/or PV reference modules and/or other devices for accurately measuring solar insolation 303; devices for measuring ambient temperature and wind speed 304; devices for measuring the temperature of the PV modules 304; devices for measuring the spectrum of the incident solar insolation 304; and a site computer 305 that receives signals, performs data analysis, diagnoses system performance, and optionally transmits the data to a remote computer 306 for analysis and/or remote access.

String Combiner with I-V Measurement Capability

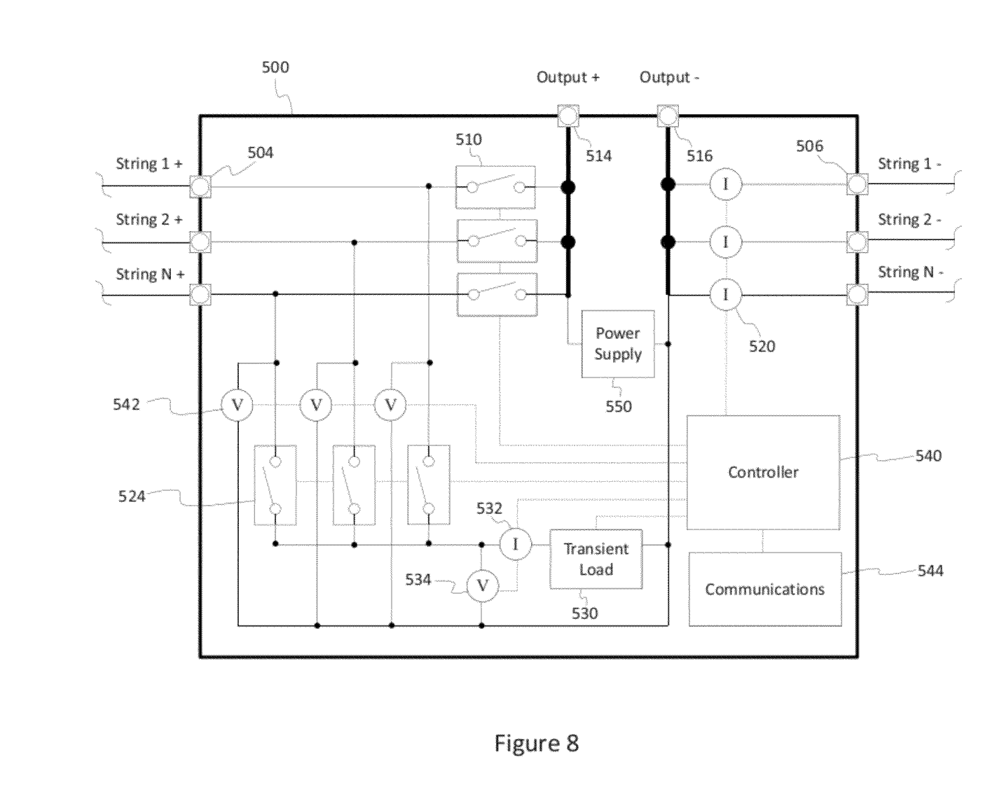

FIG. 8 depicts a block diagram of the PV string combiner with integrated I-V measurement system. The string combiner 500 comprises a weather-proof protective enclosure, positive and negative terminals for connecting the PV strings 504, 506, positive and negative terminals for the combined output 514, 516, circuitry for disconnecting each string from the combined output and measuring its I-V characteristics, a controller 540, and a communications element 544. Inputs from three strings are shown for illustration; however, the string combiner 500 may be designed to accommodate any practical number of strings, such as 8, 16, 32, or larger numbers. As more strings are combined, the cost of the I-V measurement circuitry and control and communications functions is reduced on a per-string basis.

In order to perform I-V measurement on a given string, the string is disconnected from the output using its associated “disconnect switch” 510 and subsequently connected to the transient load 530 using an associated “measurement switch” 524. Transient load 530 draws a variable current from the connected string ranging from 0 to the short circuit current Isc, causing the string voltage to vary from the open circuit voltage Voc to near 0. During this time the string current and voltage are measured by the current measurement circuit 532 and voltage measurement circuit 534, in order to measure the string I-V characteristics. When measurement is complete, the switches 524, 510 are returned to their normal positions, reconnecting the string to the output.

The switch elements 510 and 524 are depicted as mechanical relays for illustration, but may also be implemented using semiconductor devices or other suitable switching elements.

The transient load 530 may be implemented using any of a number of methods, including, but not limited to, charging of a capacitor, dissipation of power in a variable-resistance semiconductor device (“electronic load”), or variable DC-DC transfer of power to another load. The swing time between Isc and Voc should be on the order of 1 to 100 ms, depending on the characteristics of the PV modules. Longer times favor better measurement by the measurement circuits 532, 534 but result in greater power dissipation in the transient load 530 and greater potential for change in insolation conditions during the measurement.

Minimization of power dissipation in the transient load 530 is critical since typical PV strings may generate up to 5000 W at maximum power.

In one embodiment, the transient load 530 is implemented using variable DC-DC transfer of power to a simple dissipative load such as a resistor. In another embodiment, not depicted in FIG. 8, variable DC-DC transfer is used to transfer power to the output terminals of the string combiner 500, in order to minimize internal power dissipation during the measurement.

The voltage and current measurement circuits 532, 534 should have precision better than 1%, and preferably better than 0.2%.

The string combiner 500 includes a controller 540 that controls the operation of the device, records data from the measurement circuits, and communicates with an external computing system via the communications element 544. The controller 540 may comprise, for example, a microcontroller and non-volatile memory. The communications element 544 may comprise a wired or wireless communication link.

Power to operate the functions of the switches and the measurement, control, and communication circuits may either be provided by an external power source (not shown) or derived from the PV array using a power supply 550 internal to the string combiner 500. The power supply 550 may be implemented, for example, as a DC-DC converter drawing a small current from the PV array, and may further comprise an energy storage device.

In addition to the intermittent current and voltage measurement provided by the measurement circuits 532, 534, the string combiner 500 may include continuous current sensors 520 and/or voltage sensors 542 for each string. These allow measurement of string current and voltage during normal operation, when the string is not connected to the transient load 530. The current sensors 520 and/or voltage sensors 542 may either have low precision or high precision. Low precision sensors may be used for an embodiment in which the sensors 520, 542 provide continuous monitoring while the measurement circuits 532, 534 provide intermittent high-precision measurements. In another embodiment, high precision sensors 520, 542 eliminate the need for one or both of the measurement circuits 532, 534. In another embodiment, low precision sensors 520, 542 are periodically and automatically recalibrated using measurement circuits 532, 534. In this embodiment, high-precision continuous measurement may be achieved using relatively lower cost devices on each string.

The switches, sensors, and measurement circuits could be re-arranged to appear on either the high (positive) or low (negative) side of the string combiner 500 circuit and various configurations are understood to be functionally equivalent.

### Transient Measurements

In another embodiment, not depicted in FIG. 8, the I-V system 530 or other test system includes the capability to apply a transient electrical signal to the one or multiple strings of PV modules, and the controller 540 may analyze transient signals from the one or multiple strings in order to identify and/or locate fault conditions, including but not limited to individual or multiple PV modules comprising the one or multiple strings that are damaged, degraded, or otherwise performing abnormally.

### Disconnect Switch

Implementation of the disconnect switch 510 is non-trivial, since the device must be capable of interrupting typical DC currents ranging from 5-15 A at voltages ranging from 500 to 1000 V. Furthermore, the switch should have low series resistance resulting in power loss from the string of less than 15 W, and preferably less than 5 W, during normal operation of the string. In addition, the disconnect switch 510 should have relatively low cost, since the cost will be multiplied by the number of strings in the string combiner 500.

In one embodiment, the disconnect switch 510 is implemented using a mechanical relay with appropriate arc-suppression components for DC switching, such as a blowout magnet and/or snubber circuit. However, DC relays for the required current and voltage ranges typically have considerable cost.

In another embodiment, the disconnect switch 510 is implemented using one or more semiconductor devices such as bipolar or MOSFET transistors. However, such devices may introduce excessive series resistance, resulting in undesirable power loss.

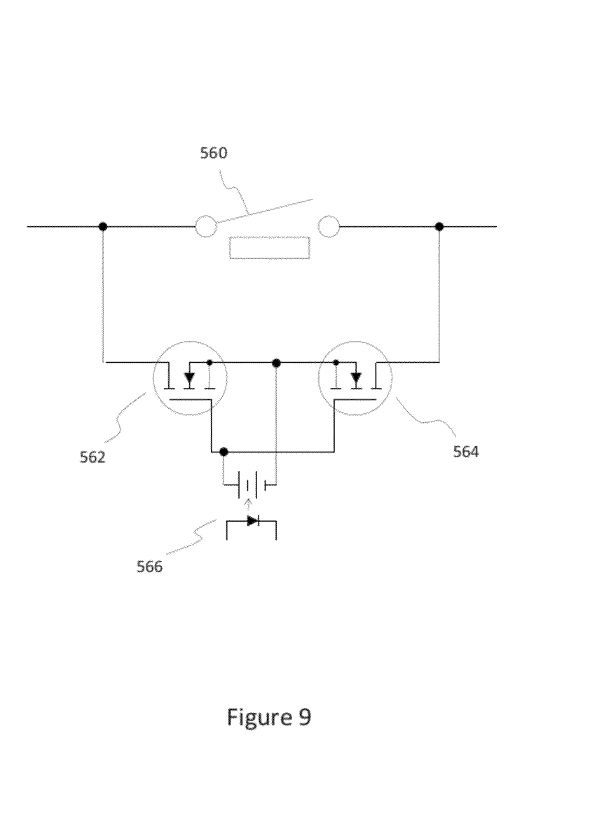

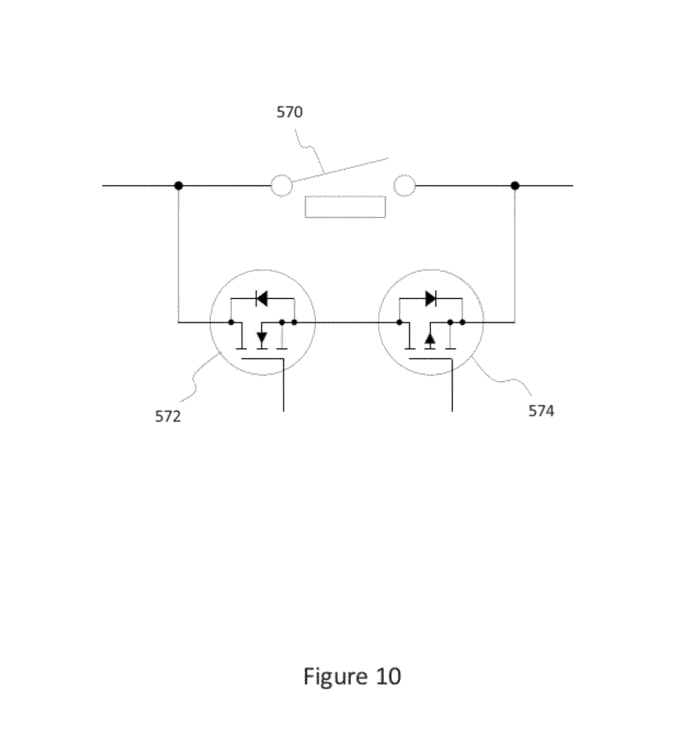

Alternatively, the disconnect switch 510 may be implemented by combining both relays and transistor devices in order to use the benefits of each. A relay may be placed in parallel with a transistor-based switch, wherein the relay provides a low series resistance conduction path when closed, and the transistor-based switch is made to conduct prior to and during the opening of the relay contacts to suppress arcs and protect the relay. FIG. 9 depicts an exemplary embodiment in which a relay 560 is in parallel with a bi-directional switch similar to a “solid-state relay” comprising two n-channel MOSFET devices 562, 564 controlled by a photovoltaic opto-isolator 566. FIG. 10 depicts another exemplary embodiment in which a relay 570 is in parallel with a bi-directional transistor switch comprising an n-channel MOSFET 572 and a p-channel MOSFET 574 in series.

These examples depict bi-directional transistor switches which protect the relays 560, 570 against current flow in both directions. In alternative embodiments, the transistor-based switches are uni-directional.

Apart from the examples shown, other similar configurations may be used to protect the relays 560, 570 during switching.

### String-Combiner Functions

In one embodiment, the string combiner box 302 may include instrumentation enabling monitoring individual string operating currents to a high degree of accuracy, isolating any number of the strings 301 combined in parallel from all other strings and from the inverter, performing full current and voltage measurements on one isolated string at a time, storing and analyzing data and uploading the raw and/or analyzed data to a remote computer 306 via wireless or wired communication.

In another embodiment, the string combiner box 302 also includes inputs for a single or multiple reference devices 303 (calibrated PV reference cells and/or calibrated PV reference modules and/or other calibrated reference devices), so that the string combiner box may record and/or transmit solar insolation data contemporaneously with the string level monitoring and/or current and voltage sweep data.

In yet another embodiment, the string combiner box 302 also includes inputs for a master reference calibration device that can be used to calibrate other calibrated reference devices in the field.

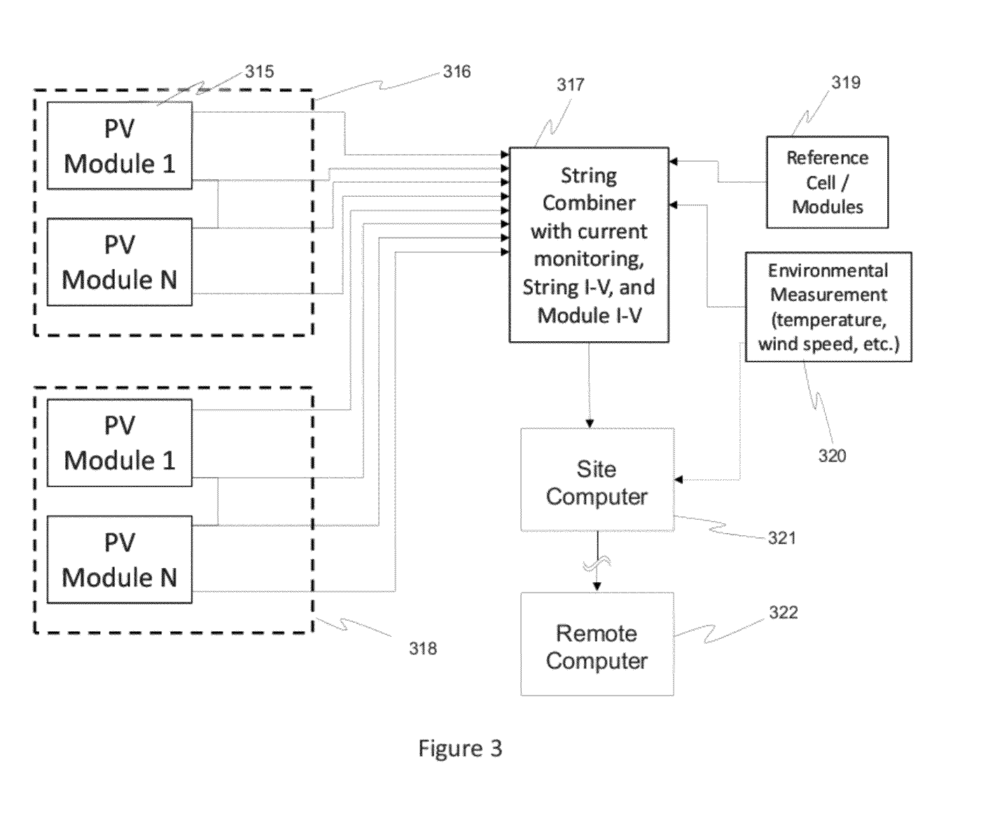

Referring now to FIG. 3 which depicts an alternate embodiment. FIG. 3 depicts a block diagram showing a string combiner box 317 capable of both accurate string level current monitoring, string level I-V sweeps, and module level I-V sweeps. Illustrated in FIG. 3 are two strings of PV modules 316 and 318 comprised of PV modules 315, connected in parallel at the string combiner box 317, a group of calibrated reference PV cells or PV modules 319 connected to the string combiner box 317, environmental measurement instrumentation 320 such as ambient thermometers and anemometers, a site computer 321 and a remote computer 322. The string combiner box 317 is capable of not just isolating individual strings of PV modules 316, 318, but also includes inputs for individual PV modules 315 and would be capable of isolating individual PV modules 315 from their respective strings 316 in order to take full I-V curves of each individual PV module 315. In this embodiment the string combiner box 317 would be capable of isolating individual strings 316, 318 and performing full I-V sweeps of individual strings 316, 318, and would also be capable of isolating individual PV modules 315 from a string 316 in order to take full I-V curves of the individual PV module 315. In this embodiment, the PV reference modules 319, the environmental measurement components 320, the site computer 321, and the remote computer 322 have similar functions as described above.

In one embodiment, some or all of the electrical connections between each string and the components of the string combiner box capable of performing I-V sweep measurements are four-wire Kelvin connections.

### Module-Level Measurements

In the discussion of the systems and methods for PV string level measurements and analysis of PV string level performance and degradation included in the disclosed subject matter, it should be understood that alternative embodiments enabling PV module level measurements in addition to or instead of PV string level measurements apply in all cases and that all possible measurements and analysis of PV strings should also apply to measurements and analysis of PV modules, which may be considered equivalent to strings of one module, with the exception of string I-V phenomena that arise due to the presence of bypass diodes in the PV module comprising a string, unless the PV module in question includes bypass diodes between cells or groups of cells.

### Reference Devices

In one embodiment, the solar insolation level is measured by measuring the short circuit current of multiple calibrated reference cells or modules with spectral responsivities substantially identical to the PV modules comprising the array.

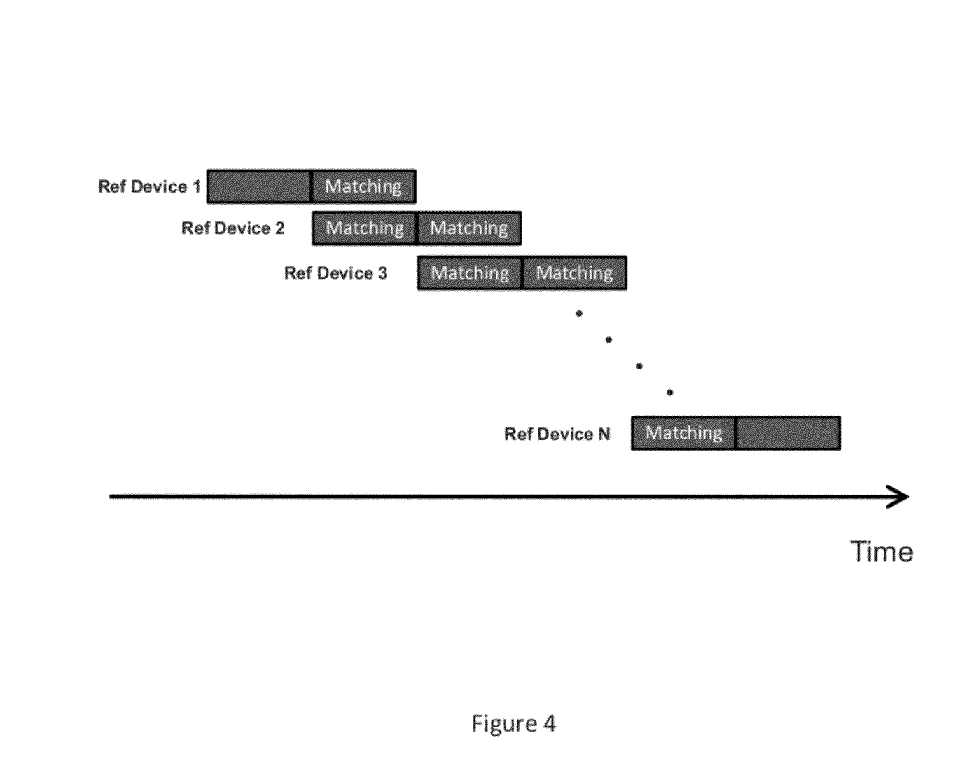

In another embodiment, reference devices are recalibrated regularly on site at staggered intervals such that solar insolation data from reference devices which are newly calibrated are recorded contemporaneously with solar insolation data from reference devices less recently calibrated. In this way relative calibration errors may be minimized. This embodiment is depicted in FIG. 4.

In another embodiment, reference devices are recalibrated regularly off site at staggered intervals such that solar insolation data from reference devices which are newly calibrated are recorded contemporaneously with solar insolation data from reference devices less recently calibrated. In this way relative calibration errors may be minimized. This embodiment is depicted in FIG. 4.

In one embodiment, some fraction of the reference devices are regularly cleaned to minimize the effects of soiling on solar insolation measurement. In this embodiment, the performances of the reference devices may be regularly compared as a function of incident angle of solar irradiation in order to detect the presence of soiling from the different angular responses of the cleaned and uncleaned reference devices.

In one embodiment, some fraction of the reference devices used in the system are PV modules substantially identical to the PV modules comprising the array, and are arranged in a string of PV modules substantially identical to the strings of PV modules comprising the array. In this embodiment, any string of calibrated PV reference modules would be operated similarly to typical strings of PV modules in the array, and would be recalibrated regularly and compared to other reference devices not similarly arranged in order to isolate any degradation effects with causes related to the arrangement of the modules in strings.

In yet another embodiment, some fraction of the calibrated solar insolation reference devices are calibrated reference PV cells, for which the uncertainty in a single solar insolation measurement may be as low as approximately +/−1.3%, while other calibrated solar insolation reference devices are calibrated reference PV modules substantially identical to those PV modules comprising the array.

### General

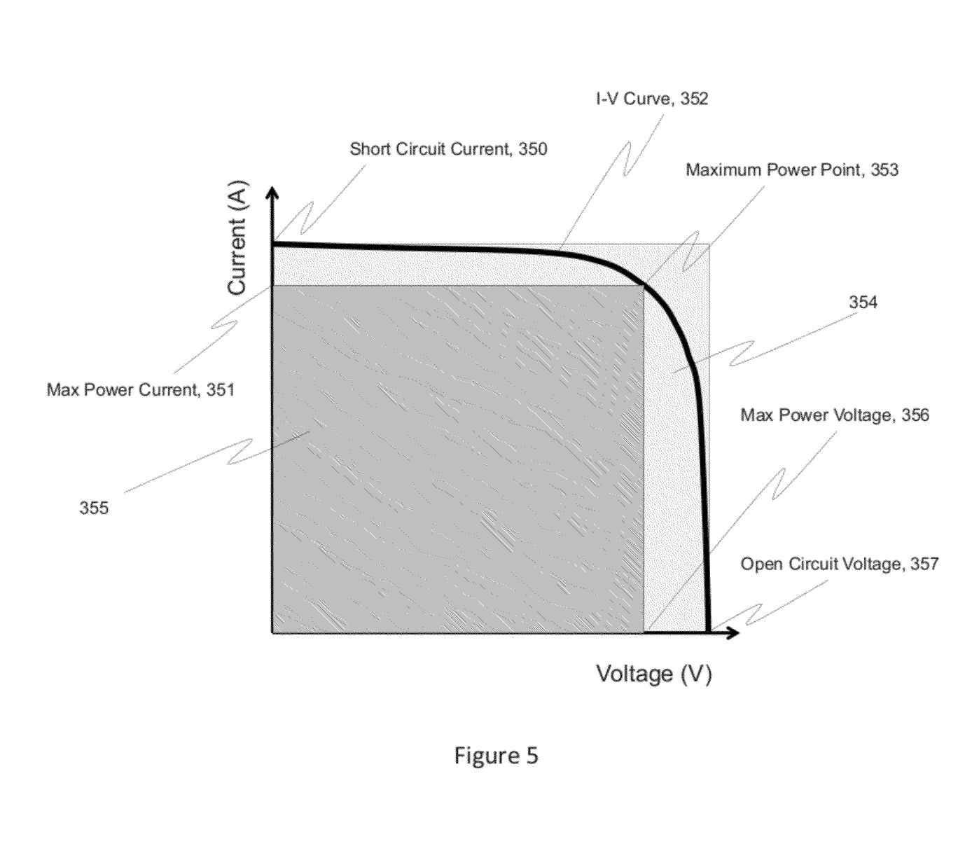

FIG. 5 illustrates an ideal illuminated I-V curve 352 of a PV cell, PV module, or string of PV modules with the short circuit current 350, open circuit voltage 357, maximum power operating point 353, maximum power current 351, and the maximum power voltage 356 all indicated. Also indicated is the area in the power plane 355 of the maximum power current 351 multiplied by the maximum power voltage 356, as well as the area in the power plane 354 of the short circuit current 350 multiplied by the open circuit voltage 357. The fill factor of the PV cell, PV module, or PV strings defined as the smaller area indicated 355 divided by the larger area indicated 354.

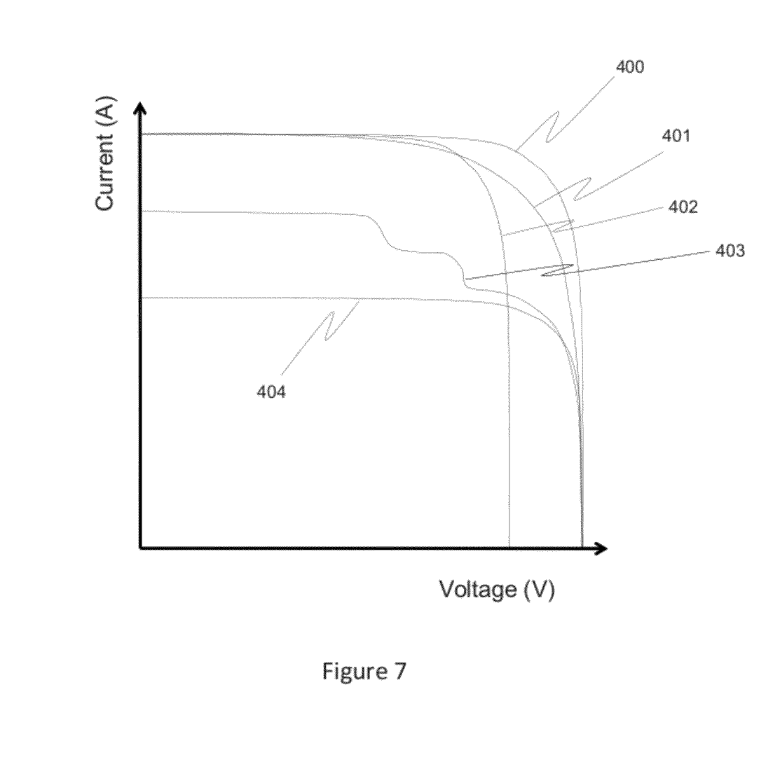

FIG. 7 depicts multiple I-V curves of a string, illustrating several of the ways in which non-ideal behavior may be exhibited in the I-V curve. Curve 400 is an ideal I-V curve, curve 401 depicts an I-V curve with a reduced fill factor (due to e.g., an increase in series resistance or recombination), curve 402 depicts an I-V curve with a reduced open circuit voltage, curve 403 depicts an I-V curve in which one or more modules incorporating bypass diodes in the string are partially shaded, and curve 404 depicts an I-V curve of a string with a reduced short circuit current (due to e.g., soiling).

### Compensation for Temperature Effects

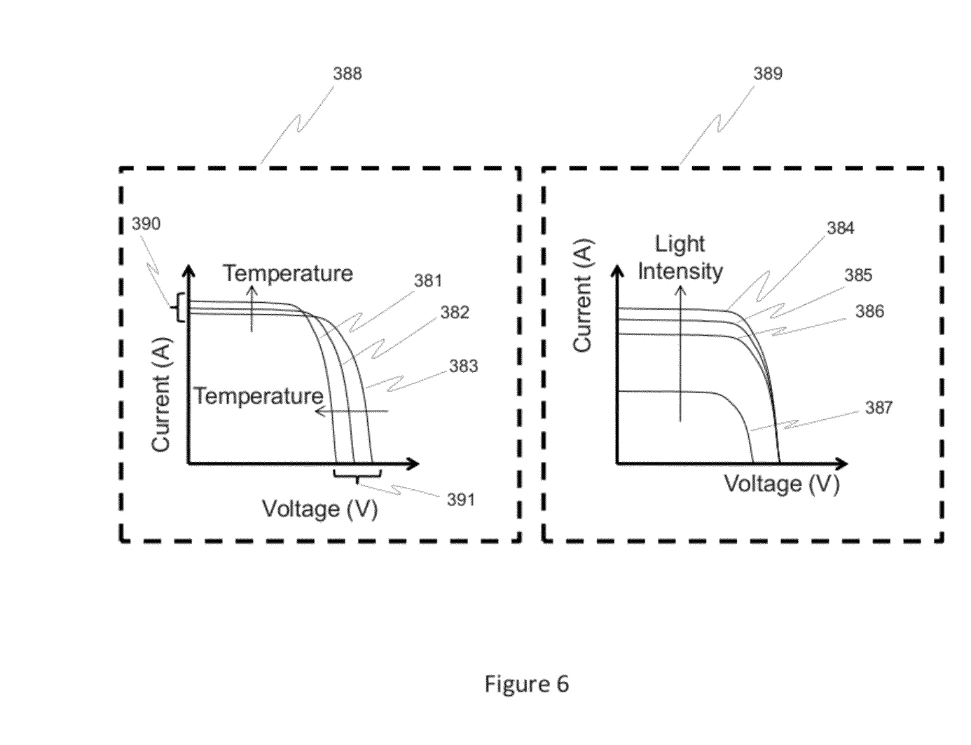

One of the largest sources of uncertainty of PV module and string efficiency and performance measurements is the device temperature. That is because PV device temperature affects the I-V curves of PV devices independently of light intensity, as is depicted in FIG. 6. Back temperatures of PV devices may be easily measured with thermocouples or other similar devices affixed to each device, but large PV arrays are typically comprised of at least thousands of PV modules, rendering such an approach impractical and expensive. Therefore it is desirable to be able to accurately compensate for temperature effects on PV device I-V curves without using a thermocouple or other temperature measurement device to physically measure the temperature of each module.

FIG. 6 depicts the effects on an ideal illuminated I-V curve of a PV cell, PV module, or string of PV modules with varying temperature 388 and varying light intensity 389. In the group of I-V curves depicting the effects of varying temperature 381-383, three I-V curves are shown for temperatures T1, T2, and T3, for which T1>T2>T3. I-V curve 381 corresponds to temperature T1, I-V curve 382 corresponds to temperature T2, and I-V curve 383 corresponds to temperature T3. In the group of I-V curves depicting the effects of varying light intensity 384-387, four I-V curves are shown for light intensities I1, I2, I3, and I4, for which I1>I2>I3>I4. I-V curve 384 corresponds to light intensity I1, I-V curve 385 corresponds to light intensity I2, I-V curve 386 corresponds to light intensity I3, and I-V curve 387 corresponds to light intensity I4. Above certain insolation levels the open circuit voltage (Voc) 391 depends primarily on temperature, and when coupled with solar insolation data taken from calibrated reference devices may be used to compensate for the effects of temperature on string level I-V curves. Once a calibration of I-V parameters with device temperatures has been performed, this type of analysis allows for accurate correction of temperature effects without actually measuring device temperatures.

Various methods may be used for calibrating and quantifying the effects of temperature on string level I-V measurements. The following paragraphs detail various methods that may be employed to achieve that aim.

In one embodiment, temperatures of some fraction of the calibrated PV reference device(s) 303 are accurately measured and correlated with full I-V characteristics of the reference device(s) 303 in order to correlate temperature changes with parameters extracted from the I-V curves 381, 382, 383 such as, but not limited to, open circuit voltage 391, short circuit current 390, and fill factor.

For example, as is depicted in FIG. 6 it is apparent that short circuit current 390 should increase with device temperature while open circuit voltage 391 should decrease with device temperature. While the short circuit current 390 is also a function of light intensity, above a certain light intensity level the open circuit voltage 391 saturates and is primarily a function of device temperature 384-387. By independently measuring device temperature it is possible to correct the short circuit current 390 for temperature effects and determine the open circuit voltage 391 as a function of temperature.

In one embodiment, ambient temperature measurements are made using ambient thermometers, and may be correlated with wind speed measurements to provide an estimate of the PV reference device temperature(s). Full current and voltage (I-V) curves 381-387 are made on the one or multiple reference device(s) in the power generating quadrant of the current and voltage plane so that the temperature estimate(s) of the PV reference device(s) may be correlated with device parameters of the reference device(s) such as, but not limited to, open circuit voltage 391, short circuit current 390, and fill factor.

In one embodiment, some fraction of the PV reference devices for which temperature measurements or estimates have been correlated with device parameters such as, but not limited to, open circuit voltage 391, short circuit current 390, and fill factor, are calibrated PV modules substantially identical to the PV modules comprising the array, so that the device parameters extracted from string I-V sweeps of the PV modules comprising the array may be used to accurately extract or estimate the temperatures of the PV modules comprising the array.

In another embodiment, some fraction of the PV reference devices 303 are PV modules substantially identical to the PV modules comprising the array, and are arranged in one or more strings substantially identical to the PV strings comprising the array. In this embodiment, the temperatures of these calibrated PV reference modules 303 are independently measured and correlated with the I-V parameters of that string so that the I-V parameters of all other strings comprising the array may also be correlated with the PV module temperatures comprising each string.

In one embodiment, some fraction of the PV reference devices are periodically replaced with new, calibrated PV reference devices in order to eliminate the effects of performance degradation on that subset of reference devices.

### Stored Modules

In yet another embodiment, some number of pristine PV modules identical to the PV modules comprising the array are stored at an environmentally controlled location by a third party other than the PV manufacturer and the operator of the PV array, and are not permanently incorporated into the PV array. Full I-V curve and efficiency measurements are carried out on these stored PV modules at some regular interval (e.g., annually) in order to have access to performance data from a group of PV modules not subject to the same degradation mechanisms as the PV modules comprising the PV array.

### Data Analysis and Diagnostic Capabilities

In another embodiment, the string combiner box 302 and/or system computer 305 and/or remote computer 306 can implement algorithms capable of automatically analyzing the string I-V curves 381-387 and/or monitoring data, incorporating solar insolation data from the calibrated reference device(s) 303, and may also be capable of incorporating environmental data from other instruments (including, but not limited to, ambient thermometers and anemometers) 304, in order to determine whether or not individual strings are performing within the defined acceptable performance limits, and if not, automatically assign causes for the reason for abnormal string performance, including but not limited to, soiling of all or some modules in the string, shading of all or some modules in the string, increase of series resistances of some or all modules in the string, decrease in shunt resistances of some or all modules in the string, a ground fault in the string, etc.

### Noise Analysis

In another embodiment, the string combiner box 302 and/or system computer 305 and/or remote computer 306 incorporate instrumentation and/or algorithms capable of measuring the electrical noise from each string, and correlating that noise with assignable causes for abnormal string performance including but not limited to soiling of all or some modules in the string, shading of all or some modules in the string, increase of series resistances of some or all modules in the string, decrease in shunt resistances of some or all modules in the string, a ground fault in the string, or a failure of the inverter itself.

### Inverter Degradation

In one embodiment, the full string I-V and absolute efficiency measurements of the strings comprising the PV array are used to monitor the performance of the PV inverter(s) incorporated into the array over time, so that decreases in efficiency or faults of the PV inverter(s) are detected by comparing the absolute DC efficiencies of the PV module strings comprising the array with the AC electrical energy generated at the output(s) of the inverter(s).

### Dark I-V

In one embodiment, the string combiner box 302 also includes power supplies and associated electronics enabling performance of “dark” I-V curve measurement of strings of PV modules 301, i.e. measurement of I-V data when the PV modules are not illuminated. In this embodiment, the string combiner box 302 and/or site computer 305 and/or remote computer 306 may be capable of implementing algorithms for extracting parameters of interest from string or PV module dark I-V data such as, but not limited to, series resistance, shunt resistance, and diode ideality factors.

### Computing System

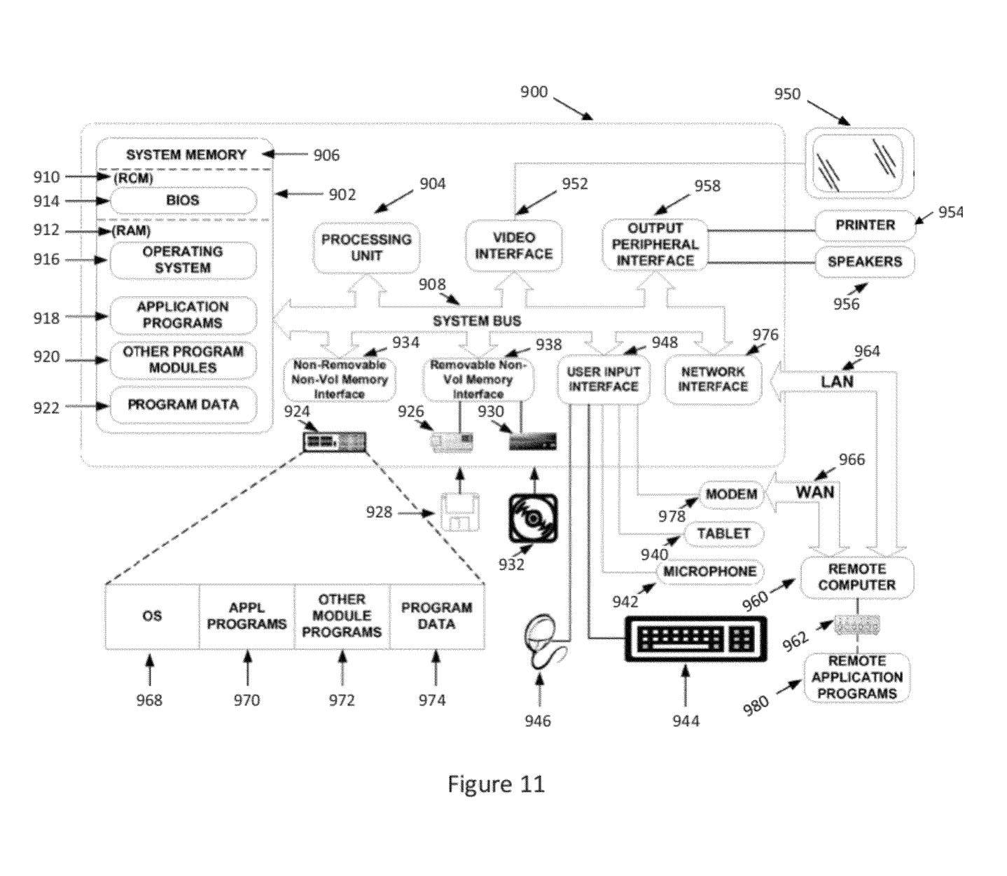

With reference to FIG. 11, an exemplary computer system 900 for implementing the disclosed subject matter includes a general purpose computing device in the form of a computing system 900, commercially available from Intel, IBM, AMD, Motorola, Cyrix and others. Components of the computing system 902 may include, but are not limited to, a processing unit 904, a system memory 906, and a system bus 908 that couples various system components including the system memory to the processing unit 904. The system bus 908 may be any of several types of bus structures including a memory bus or memory controller, a peripheral bus, and a local bus using any of a variety of bus architectures.

Computing system 900 typically includes a variety of computer readable media. Computer readable media can be any available media that can be accessed by the computing system 900 and includes both volatile and nonvolatile media, and removable and non-removable media. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data.

Computer memory includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by the computing system 900.

The system memory 906 includes computer storage media in the form of volatile and/or nonvolatile memory such as read only memory (ROM) 910 and random access memory (RAM) 912. A basic input/output system 914 (BIOS), containing the basic routines that help to transfer information between elements within computing system 900, such as during start-up, is typically stored in ROM 910. RAM 912 typically contains data and/or program modules that are immediately accessible to and/or presently being operated on by processing unit 904. By way of example, and not limitation, an operating system 916, application programs 918, other program modules 920 and program data 922 are shown.

Computing system 900 may also include other removable/non-removable, volatile/nonvolatile computer storage media. By way of example only, a hard disk drive 924 that reads from or writes to non-removable, nonvolatile magnetic media, a magnetic disk drive 926 that reads from or writes to a removable, nonvolatile magnetic disk 928, and an optical disk drive 930 that reads from or writes to a removable, nonvolatile optical disk 932 such as a CD ROM or other optical media could be employed to store parts of the invention of the present embodiment. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 924 is typically connected to the system bus 908 through a non-removable memory interface such as interface 934, and magnetic disk drive 926 and optical disk drive 930 are typically connected to the system bus 908 by a removable memory interface, such as interface 938.

The drives and their associated computer storage media, discussed above, provide storage of computer readable instructions, data structures, program modules and other data for the computing system 900. For example, hard disk drive 924 is illustrated as storing operating system 968, application programs 970, other program modules 972 and program data 974. Note that these components can either be the same as or different from operating system 916, application programs 920, other program modules 920, and program data 922. Operating system 968, application programs 970, other program modules 972, and program data 974 are given different numbers hereto illustrates that, at a minimum, they are different copies.

A user may enter commands and information into the computing system 900 through input devices such as a tablet, or electronic digitizer, 940, a microphone 942, a keyboard 944, and pointing device 946, commonly referred to as a mouse, trackball, or touch pad. These and other input devices are often connected to the processing unit 904 through a user input interface 948 that is coupled to the system bus 908, but may be connected by other interface and bus structures, such as a parallel port, game port or a universal serial bus (USB).

A monitor 950 or other type of display device is also connected to the system bus 908 via an interface, such as a video interface 952. The monitor 950 may also be integrated with a touch-screen panel or the like. Note that the monitor and/or touch screen panel can be physically coupled to a housing in which the computing system 900 is incorporated, such as in a tablet-type personal computer. In addition, computers such as the computing system 900 may also include other peripheral output devices such as speakers 956 and printer 954, which may be connected through an output peripheral interface 958 or the like.

Computing system 900 may operate in a networked environment using logical connections to one or more remote computers, such as a remote computing system 960. The remote computing system 960 may be a personal computer, a server, a router, a network PC, a peer device or other common network node, and typically includes many or all of the elements described above relative to the computing system 900, although only a memory storage device 962 has been illustrated. The logical connections depicted include a local area network (LAN) 964 connecting through network interface 976 and a wide area network (WAN) 966 connecting via modem 978, but may also include other networks. Such networking environments are commonplace in offices, enterprise-wide computer networks, intranets and the Internet.

The central processor operating pursuant to operating system software such as IBM OS/2®, Linux®, UNIX®, Microsoft Windows®, Apple Mac OSX® and other commercially available operating systems provides functionality for the services provided by the present invention. The operating system or systems may reside at a central location or distributed locations (i.e., mirrored or standalone).

Software programs or modules instruct the operating systems to perform tasks such as, but not limited to, facilitating client requests, system maintenance, security, data storage, data backup, data mining, document/report generation and algorithms. The provided functionality may be embodied directly in hardware, in a software module executed by a processor or in any combination of the two.

Furthermore, software operations may be executed, in part or wholly, by one or more servers or a client's system, via hardware, software module or any combination of the two. A software module (program or executable) may reside in RAM memory, flash memory, ROM memory, EPROM memory, EEPROM memory, registers, hard disk, a removable disk, a CD-ROM, DVD, optical disk or any other form of storage medium known in the art. An exemplary storage medium is coupled to the processor such that the processor can read information from, and write information to, the storage medium. In the alternative, the storage medium may be integral to the processor. The processor and the storage medium may also reside in an application specific integrated circuit (ASIC). The bus may be an optical or conventional bus operating pursuant to various protocols that are well known in the art.

### Array Subsections

While in the foregoing description of the disclosed subject matter PV module “strings” have been described as series-connected groups of PV modules, it should be understood that “strings” might also comprise groups of parallel-connected modules or combinations of series- and parallel-connected groups, and that the disclosed embodiments apply to any such configuration. Furthermore, the disclosed embodiments may apply even to measurement of individual modules within a PV array. More generally, the disclosed subject matter deals with a system and methods for measuring array subsections, where such subsections may be individual modules, series-connected strings, etc.

### CONCLUSION

Although example diagrams to implement the elements of the disclosed subject matter have been provided, one skilled in the art, using this disclosure, could develop additional hardware and/or software to practice the disclosed subject matter and each is intended to be included herein.

In addition to the above described embodiments, those skilled in the art will appreciate that this disclosure has application in a variety of arts and situations and this disclosure is intended to include the same.

What is claimed is:

1. A system for monitoring the performance of an array of photovoltaic (PV) modules, comprising:
a plurality of PV modules;
one or more I-V measurement systems, said I-V measurement systems measuring I-V data, said I-V data including current versus voltage data;
one or more switching systems each of which alternately connects one or more array subsections to said I-V measurement systems, said array subsections comprised of one or more PV modules; and
a computing system which records and analyzes said I-V data to determine performance characteristics of said array subsections.

2. The system of claim 1, wherein said array subsections comprise strings, said strings comprising a plurality of PV modules connected in series and/or parallel combinations.

3. The system of claim 2, wherein said strings have electrical outputs, and where said electrical outputs are combined in a string combiner to aggregate the output power of said strings.

4. The system of claim 2, wherein said computing system analyzes said I-V data for I-V curve characteristics indicative of mismatched PV modules or groups of PV modules comprising one or more of said strings.

5. The system of claim 1, further comprising at least one temperature measurement device for measuring an ambient temperature and/or a temperature of at least one PV module.

6. The system of claim 5, wherein said computing system corrects said I-V data in response to said temperature measurement device for the effects of temperature variation.

7. The system of claim 5, wherein ambient temperature measurements are made using ambient thermometers, and said ambient temperature measurements are correlated with wind speed measurements to provide an estimate of a PV reference device and/or array subsection temperature(s).

8. The system of claim 5, wherein temperature measurements from said temperature measurement device and/or estimates of temperature are correlated with current and voltage data from one or more PV reference device(s) so that said temperature measurement(s) and/or said temperature estimate(s) of said PV reference device(s) are correlated with device parameters of said PV reference device(s), said device parameters including Voc, Isc, and/or FF.

9. The system of claim 5, wherein one or more PV reference devices for which temperature measurements and/or temperature estimates have been correlated with device parameters, said device parameters including Voc, Isc, and/or FF, are calibrated PV modules substantially identical to said PV modules in said array subsection, so that said device parameters extracted from said I-V data of said array subsection are used to accurately extract or estimate the temperature(s) of said PV module(s) in said array subsection.

10. The system of claim 5, wherein one or more PV reference devices are PV modules substantially identical to said PV modules in one or more array subsection(s), and said PV reference devices are arranged in one or multiple groups substantially identical to the groups comprising said array subsection(s), and wherein the temperatures of said PV reference modules are measured and/or estimated and correlated with said device parameters of said PV reference device array subsection so that said device parameters of one or more other array subsection(s) may also be correlated with the PV module temperatures comprising each array subsection.

11. The system of claim 5, wherein one or more insolation measurement devices are periodically replaced with new, calibrated insolation measurement devices in order to eliminate the effects of performance degradation on said insolation measurement devices.

12. The system of claim 1, further comprising a spectrometer, said spectrometer measuring the spectrum of incident solar radiation, wherein said computing system corrects said I-V data for the spectral mismatch between incident solar radiation and a standard reference spectrum.

13. The system of claim 1, wherein said I-V measurement systems comprise a transient load, said transient load comprised of:
a capacitor which is charged by said array subsection;
a variable-resistance electronic load; or
a variable DC to DC power transfer system.

14. The system of claim 1, wherein said I-V measurement systems comprise a transient load, said transient load comprised of a variable DC to DC power transfer system, said variable DC to DC power transfer system transferring power from said array subsection to another array subsection or the output of a string combiner.

15. The system of claim 1, wherein said switching systems, said I-V measurement systems, and/or said computing system are at least partially powered by at least one of said array subsections.

16. The system of claim 1, further comprising current and/or voltage sensors measuring current and/or voltage, respectively, of array subsections independently of said switching systems and I-V measurement systems.

17. The system of claim 16, wherein said current and/or voltage sensors are periodically recalibrated by comparison to measurements performed with said I-V measurement systems.

18. The system of claim 1, wherein said switching systems are implemented using mechanical relays and/or semiconductor switching devices.

19. The system of claim 18, wherein said mechanical relay is placed in parallel with said semiconductor device, said semiconductor device a transistor-based switch, wherein said mechanical relay provides a low series resistance conduction path when closed, and said transistor-based switch is made to conduct during the opening or closing of said mechanical relay contacts to suppress arcs and protect said mechanical relay.

20. The system of claim 1, further comprising at least one reference device for solar insolation measurement.

21. The system of claim 20, further comprising an input for a master insolation reference device, wherein said master insolation reference device is used to calibrate said reference devices.

22. The system of claim 20, wherein a solar insolation level is measured by measuring the short circuit current of a single or multiple calibrated reference cells or modules with spectral responsivities substantially identical to the PV modules comprising the single or multiple array subsections.

23. The system of claim 20, wherein reference devices are recalibrated regularly on site and/or off site at staggered intervals such that solar insolation data from reference devices which are newly calibrated are recorded contemporaneously with solar insolation data from reference devices less recently calibrated.

24. The system of claim 20, wherein some fraction of the reference devices are regularly cleaned to minimize the effects of soiling on solar insolation measurement, and wherein the performances of the reference devices may be regularly compared as a function of incident angle of solar irradiation to detect the presence of soiling from the different angular responses of the cleaned and uncleaned reference devices.

25. The system of claim 20, wherein some fraction of the reference devices used in the system are PV modules substantially identical to the PV modules comprising the array, and are arranged in a string of PV modules substantially identical to the strings of PV modules comprising the array.

26. The system of claim 20, wherein said computing system analyzes insolation data and said I-V data to compute the efficiency (η) of said array subsections.

27. The system of claim 1, wherein said computing system analyzes said I-V data to determine at least one of open circuit voltage (Voc), short circuit current (Isc), fill factor (FF), inverse of the slope of the I-V curve at or near Voc (Roc), inverse of the slope of the I-V curve near Isc (Rsc), shunt resistance (Rsh), or series resistance (Rs) corresponding to said I-V data.

28. The system of claim 1, wherein said computing system analyzes I-V data from one or more array subsections to detect abnormal performance of said array subsection and automatically assigns one or more causes to said abnormal performance.

29. The system of claim 28, said causes including soiling of all or some modules in said array subsection, shading of some or all modules in said array subsection, damage to and/or mismatch of some or all of said PV modules in said array subsection, increase of series resistances of some or all of said PV modules in said array subsection, decrease in shunt resistances of some or all of said PV modules in said string, and/or a ground fault in said string.

30. The system of claim 1, wherein the system incorporates instrumentation and/or algorithms capable of measuring the electrical noise from each array subsection, and correlating said electrical noise with assignable causes for abnormal performance of said array subsection.

31. The system of claim 30, said causes including soiling of all or some modules in said array subsection, shading of some or all modules in said array subsection, damage to and/or mismatch of some or all of said PV modules in said array subsection, increase of series resistances of some or all of said PV modules in said array subsection, decrease in shunt resistances of some or all of said PV modules in said string, and/or a ground fault in said string.

32. The system of claim 1, wherein said I-V data and/or efficiency measurements are used to monitor the performance of a PV inverter(s) incorporated into said array subsection over time so that decreases in efficiency or faults of said PV inverter(s) are detected by comparing the absolute DC efficiencies of said array subsections with the AC electrical energy generated at the output(s) of said PV inverter(s).

33. The system of claim 1, wherein the system includes one or more power supplies to enable the system to perform dark I-V curves of said array subsections when said PV modules in said array subsections are not illuminated.

34. The system of claim 33, wherein said computing system implements algorithms for extracting parameters of interest from said array subsection dark I-V curves, including Rs, Rsh, and/or diode ideality factors.

35. The system of claim 1, additionally comprising one or more pristine PV modules substantially identical to said PV modules in said array subsection, said pristine PV modules being stored at an environmentally controlled location by a third party other than said PV module's manufacturer and said PV module's operator, and wherein said pristine PV modules are not permanently incorporated into said array subsection, so that data taken on said pristine PV modules are not subject to the same degradation mechanisms as said PV modules in said array subsection.

36. A system for monitoring the performance of an array of photovoltaic (PV) modules, comprising:
At least one array subsection, said array subsection comprised of a plurality of PV modules, and
one or more test systems, said test systems applying and measuring transient electrical signals to at least one of said array subsections and wherein said test systems determine fault conditions and/or fault locations.
